(19) United States
(12) Patent Application Publication
(10) Pub. No.: US 2013/0235669 A1
(43) Pub. Date: Sep. 12, 2013

(54) HIGH VOLTAGE SWITCH CIRCUIT

(71) Applicants: Nicola Maglione, Monza (MB) (IT); Osama Khouri, Bellano (LC) (IT); Stefano Sivero, Capriate San Gervasio (BG) (IT)

(72) Inventors: Nicola Maglione, Monza (MB) (IT); Osama Khouri, Bellano (LC) (IT); Stefano Sivero, Capriate San Gervasio (BG) (IT)

(73) Assignee: Elpida Memory, Inc., Tokyo (JP)

(21) Appl. No.: 13/415,353

(22) Filed: Mar. 8, 2012

(51) Int. Cl. G11C 16/04; H03K 3/00; G11C 5/14

(52) U.S. Cl. 365/185.18; 327/530; 327/291

(57) ABSTRACT

Disclosed herein is a device that includes a first transistor coupled between an input terminal and an output terminal and including a control gate, a voltage-generating circuit configured to produce a voltage at the control gate of the first transistor, and a discharge circuit coupled between the input terminal of the first transistor and the control gate of the first transistor, the discharge circuit responding to a discharge signal to perform a discharge operation such that an electrical charge is discharged from the output terminal to the input terminal of the first transistor.

### FIELD OF THE INVENTION

The present invention refers to a high voltage switch circuit.

### BACKGROUND OF THE INVENTION

It is known, in the state of the art, the use of high voltage levels to perform certain tasks as, for example, reading, writing and erasing flash memory cells. The high voltage levels are voltages higher than the supply voltage of the device and are typically generated inside the integrated circuit by means of high voltage generators and routed to their destination point within the chip by high voltage switches.

The high voltage generators are embedded on the chip and constructed by charge pump circuits, voltage doubler circuits and other circuits.

The high voltage is needed to be routed to a specific block or a specific line to perform a given operation. For example, a high voltage Vp (for example equal to 18 Volt), is delivered to specific memory cells in the case of program operation of the flash memory cells.

Analogue high voltage switch (HVS) circuits are used in integrated for obtaining these tasks.

Mainly, in the state of the art, two types of high voltage switch circuits are known such as the local boosting HVS circuit shown in FIG. 1 and the level shifter shown in FIG. 2.

The output of both the circuits is connected with a drivable terminal of a transistor, as example with the gate terminal of a MOS transistor acting as a switch between an input voltage and an output voltage.

As shown in FIG. 1, the HVS circuit 1 is adapted to generate the control voltage Vg of a NMOS transistor T1 acting as a switch to allow the passage of a high voltage VHI_IN from the input terminal to the output terminal where it is indicated by VHI_OUT. The HVS circuit 1 includes first and second capacitors C1, C2 connected with the terminals of an inverter INV2 and with the respective nodes SEL and SS. The nodes SEL and SS are connected with the cathode and anode of a diode D1, respectively. A clock voltage CLK is supplied at the terminal in common between the capacitor C1 and the inverter INV2. The HVS circuit 1 includes a first MOS transistor MN1 having the gate terminal supplied with the supply voltage VDD and source and drain terminals. One of the source or drain terminals is supplied with the enable signal EN_B by means of the inverter INV1 and the other is coupled with the node SEL and also connected to a input voltage node supplied with the input voltage VHI_IN via a series of two diodes D2 and D3. The HVS circuit 1 includes a second MOS transistor MN2 having the gate terminal connected with the node SEL, and source and drain terminals coupled with the node SS and the input voltage node. The node SEL is connected with the gate terminal of the transistor T1 and at this node the voltage Vg is present.

The HVS circuit 1 has two stable states, the ON state and the OFF state.

The OFF state is obtained by keeping the enable signal EN_B at high logic level, for example the supply voltage VDD. The node SEL is kept at the low level, for example GND, through the transistor MN1 being in on state because its gate terminal is supplied with the supply voltage VDD and the NMOS transistor of the inverter INV1 is in on state. The node SEL at GND makes the NMOS transistor T1 keep off, so that the voltage VHI_IN is not applied to the VHI_OUT node. Furthermore, no boosts occur on the nodes SEL and SS through the capacitors C1 and C2, being SEL node kept biased at GND potential.

The ON state is obtained by keeping the enable signal EN_B at low logic level (i.e. at GND), so that the node SEL is pre-charged at VDD-VTHN (wherein VTHN is the threshold voltage of the transistors MN1 and MN2) through the transistor MN1 and the PMOS transistor of the inverter INV1 and the node SS is pre-charged at VDD-2VTHN through transistor MN2.

At the first falling edge of the signal CLK the node SEL is boosted down by −VDD, towards the voltage −VTHN (neglecting the parasitic capacitance at the node SEL with respect to C1) through the capacitor C1. At the same time, the node SS, by means of the inverter INV2, is boosted up to 2VDD-2VTHN (neglecting the parasitic capacitance at the node SS with respect to C2) through the capacitor C2; in this way a voltage difference of 2VDD-VTHN is settled over the diode D1. If the inequality 2VDD-VTHN>VTHD (wherein VTHD is the threshold voltage of the diode D1) is kept, the node SEL raises up to 2VDD-VTHN-VTHD (neglecting the charge sharing phenomenon between capacitances at the nodes SS and SEL).

At the following rising edge of the signal CLK, the node SEL is boosted up to 3VDD-VTHN-VTHD and, at the same time, the node SS is boosted down to VDD-2VTHN. In such a way a voltage difference of −2VDD-VTHN+VTHD is settled over the diode D1, which does not make conductive path therebetween.

Successively, after the turning on of the transistor MN2, the node SS is charged up to 3VDD-2VTHN-VTHD.

At the following falling edge of the signal CLK, the node SEL is boosted down to 2VDD-VTHN-VTHD and, at the same time, the node SS is boosted up to 4VDD-2VTHN-VTHD. In such a way the voltage difference of 2VDD-VTHN is settled over the diode D1, which make conductive path therebetween.

Successively, after the turning on of the diode D1, the node SEL is charged up to 4VDD-2VTHN-2VTHD.

At the following rising edge of the signal CLK, the node SEL is boosted up to 5VDD-2VTHN-2VTHD and, at the same time, the node SS is boosted down to 3VDD-2VTHN-VTHD. In such a way a voltage difference of 2VDD+VTHD is settled over the diode D1, which makes no-conductive path.

Therefore the voltage difference across the diode D1 is alternatively equal to −2VDD+VTHD, which is a negative value so that the diode is reversed bias, and to 2VDD-VHTN. If the inequality 2VDD-VTHN>VTHD holds, then the diode is forward biased and the circuit works correctly.

But this is a critical point at low VDDs, since the threshold voltage VTHN increases when the source-body voltage of the transistor NMOS increases, due to body effect. This implies that the former-described inequality 2VDD-VTHN>VTHD might not be satisfied when the nodes SEL and SS get very high voltages. This is because, in case that the body effect on the involved NMOS transistors increases, the threshold voltage VTHN increases, and this may unwillingly result in 2VDD-VTHN<VTHD, and also, this will result in a clamping of SEL node voltage, nullifying the HVS correct working.

The maximum voltage value that the node SS can get is VIN_HI+VDD (after a boost through the capacitor); as a consequence, after the conduction through diode D1 and a boost through capacitor C1, the maximum voltage at the node SEL can be VHI_IN+2VDD-VTHD.

A limitation to the maximum voltage at the node SEL is given by the diode

D2 and D3 which limit the voltage at the node SEL to VHI_IN+2VTHD, but this is an intentional limitation, in order to avoid the node SEL to get unsafe too high voltages. Finally the maximum voltage at the node SEL results the minimum value between VHI_IN+2VDD-VTHD and VHI_IN+2VTHD. Another critical point of the local boosting HVS circuit in FIG. 1 refers to Safe Operating Area (SOA) of the transistor MN2, particularly its turning on. In fact, in the OFF state, the transistor MN2 might have its drain terminal at very high voltage, for example the voltage VHI_IN=18 Volt, its gate terminal SEL at ground GND and its source terminal SS at about ground. When the local boosting HVS circuit is turned on by setting the enable signal EN_B=0 Volt, the voltage at the node SEL is VDD-VTHN by turning on the transistor MN2; therefore, the transistor MN2 is turning on with a very high drain-source voltage VDS (e.g. ˜18V) and this may cause snap back in some technologies. Also, the transistor MN1 has a SOA issue too when the local boosting HVS circuit is turned off; in fact, in ON state when the local boosting HVS circuit is in its steady state, the gate terminal of transistor MN1 is at the supply voltage VDD, its source terminal is even at VDD because the enable signal EN_B is at low logic state and its drain terminal SEL is at very high voltage, for example 18 volt and transistor MN1 is off. When the local boosting HVS circuit is turned off by setting the enable signal EN_B is at high logic state, the source terminal of MN1 is at ground GND and transistor MN1 is turned on with a very high drain-source voltage VDS (e.g. ˜20V) and this may cause snap back in some technologies.

A drawback of the local boosting HVS circuit in FIG. 1 is the power consumption (due to the boosting, especially in the case of passing low or medium voltage by T1 transistor) that can be suffered when a low or medium voltage has to be passed to the output.

A further drawback of the local boosting HVS circuit is due to the discharge of the high voltage path connected to the VHI_OUT and VHI_IN nodes. In the case that a discharger is coupled to the VHI_OUT node, design layout area is required wide because actually there are plural the VHI_OUT nodes and plural dischargers are needed every the plurality of the VHI_OUT lines. Moreover, even if a discharger is coupled to the VHI_IN node, the HVS shown in FIG. 1 does not control T1 transistor well such that T1 transistor unwillingly turns off before discharging all the high voltage nodes has finished completely.

FIG. 2 shows the level shifter circuit as the prior HVS circuit. The level shifter circuit includes two PMOS transistors M1 and M2 having the source terminal connected to the input voltage node supplied with the input voltage VHI_IN. The gate terminal of transistor M1 is connected with the drain terminal of transistor M2 and the gate terminal of transistor M2 is connected with the drain terminal of transistor M1. The drain terminals of the transistors M1 and M2 are respectively connected with the drain terminals of two NMOS transistors M3 and M4 having the gate terminals controlled by the enable signals EN and EN_B, where the signal EN_B is the logically inverted signal of the signal EN, and having the source terminals connected to a ground node supplied with a ground voltage GND. At the drain terminal SEL of the transistor M4 is present the control voltage Vg of a NMOS transistor T1 acting as a switch between an input node supplied with an input voltage VHI_IN and an output node supplied with an output voltage VHI_OUT. The level shifter circuit in FIG. 2 presents no power consumption in the steady state.

But it is not possible to control the rising time of the node SEL and, consequently, the rising time of the voltage VHI_OUT. In addition, the maximum voltage that may be delivered to the output node is limited to VHI_OUT=VHI_IN-VHTN. In addition, the level shifter circuit can not produce the voltage VHI_IN with enough high potential in some technologies (e.g. typically greater than 18V), due to technological limits on p channel transistors M1 and M2.

### SUMMARY OF THE INVENTION

In one embodiment, it is provided a device that includes a first transistor coupled between an input terminal and an output terminal and including a control gate, a voltage-generating circuit configured to produce a voltage at the control gate of the first transistor, and a discharge circuit coupled between the input terminal of the first transistor and the control gate of the first transistor, the discharge circuit responding to a discharge signal to perform a discharge operation such that an electrical charge is discharged from the output terminal to the input terminal of the first transistor.

In another embodiment, it is provided a device that includes an internal circuit operating on a first voltage, a first transistor including a control gate, a clock-generating circuit configured to provide a boosting clock signal, and a boost circuit configured to produce a voltage to be supplied to the control gate of the first transistor in response to the boosting clock signal provided by the clock-generating circuit, the clock-generating circuit operating on a second voltage that is higher than the first voltage.

In a further embodiment, it is provided a device that includes a first transistor coupled between an input terminal and an output terminal and including a control gate, a first input circuit configured to produce a pre-charge voltage at the control gate of the first transistor, a first boost circuit configured to produce a boost voltage at the control gate of the first transistor by boosting the control gate of the first transistor, the boost voltage and the pre-charge voltage being different from each other, and selected one of the pre-charge voltage and the boost voltage being produced at the control node to render the first transistor conductive.

### BRIEF DESCRIPTION OF THE DRAWINGS

The features and advantages of the present invention will become apparent from the following detailed description of some embodiments thereof, illustrated only by way of non-limitative example in the annexed drawings, in which:

FIG. 1 shows a conventional local boosting HVS circuit;

FIG. 2 shows a conventional level shifter circuit;

FIG. 3a shows a local boosting HVS circuit according to a first embodiment of the present invention;

FIG. 3b shows a local boosting HVS circuit according to a second embodiment of the present invention;

FIG. 3c shows a local boosting HVS circuit according to a third embodiment of the present invention;

FIG. 3d shows a local boosting HVS circuit according to a fourth embodiment of the present invention;

FIG. 4a-4c show single circuit block of the local boosting HVS circuit in FIGS. 3a-3d (CLK enable logic, discharge logic and precharge logic respectively);

FIG. 5 shows a level shifter block used in the circuit of FIGS. 3a, 3c, and 3d;

FIG. 6 shows a waveform representing a high voltage switching operation of the local boosting HVS circuit;

FIG. 7 shows a waveform representing an intermediate voltage switching operation of the local boosting HVS circuit;

FIG. 8 shows a waveform indicative of a discharging switching operation of the local boosting HVS circuit;

FIG. 9 shows a NAND device including the local boosting HVS circuit according to the invention;

FIG. 10 shows in more detail a part of the NAND device in FIG. 9.

### DETAILED DESCRIPTION OF ILLUSTRATIVE EMBODIMENTS

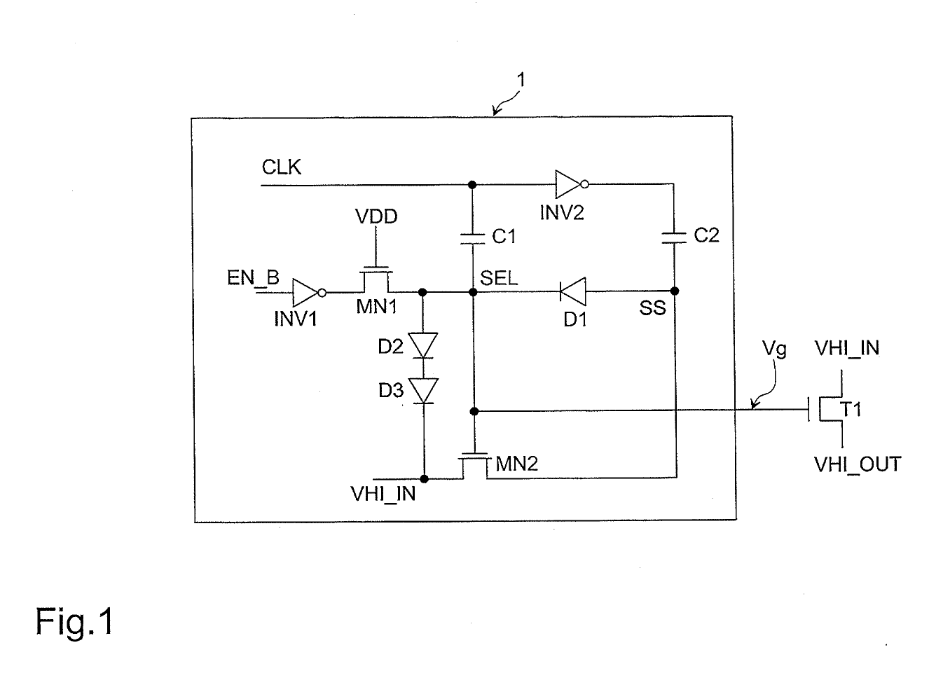

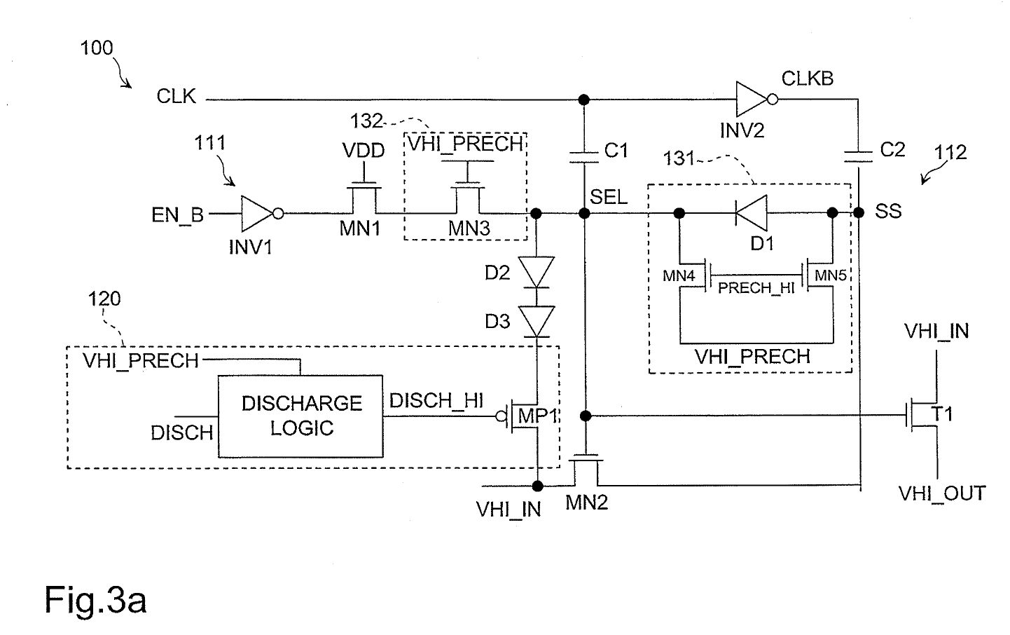

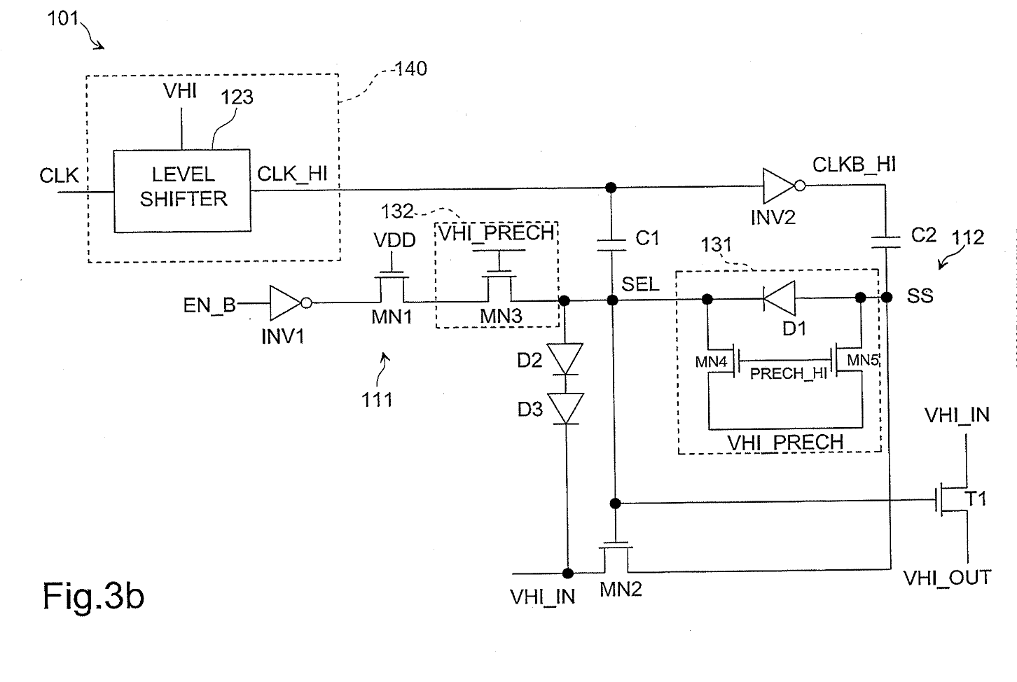

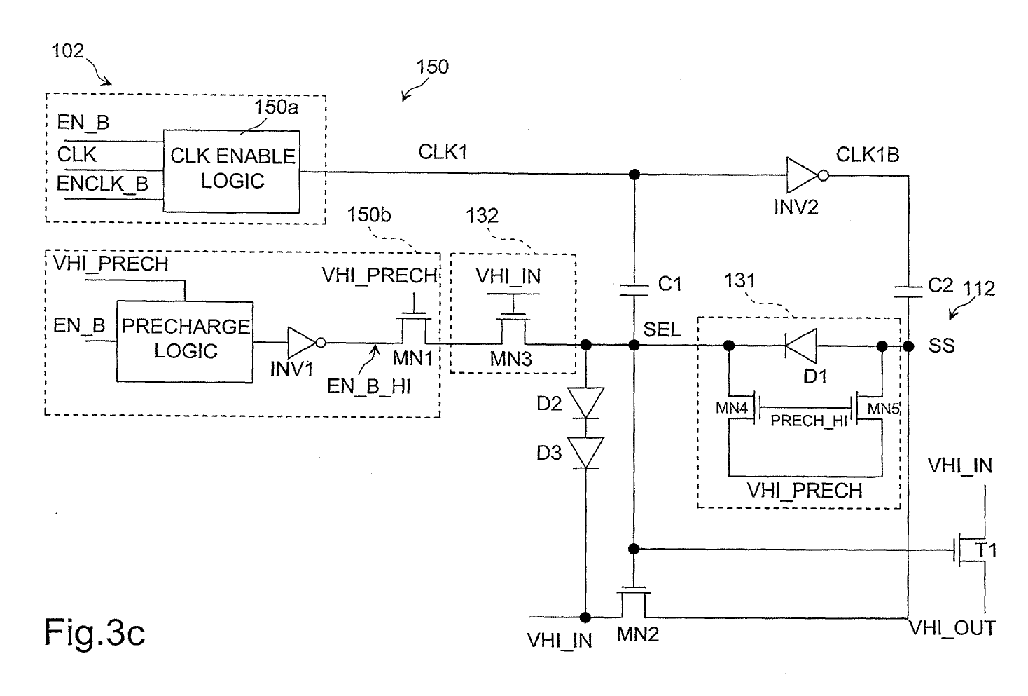

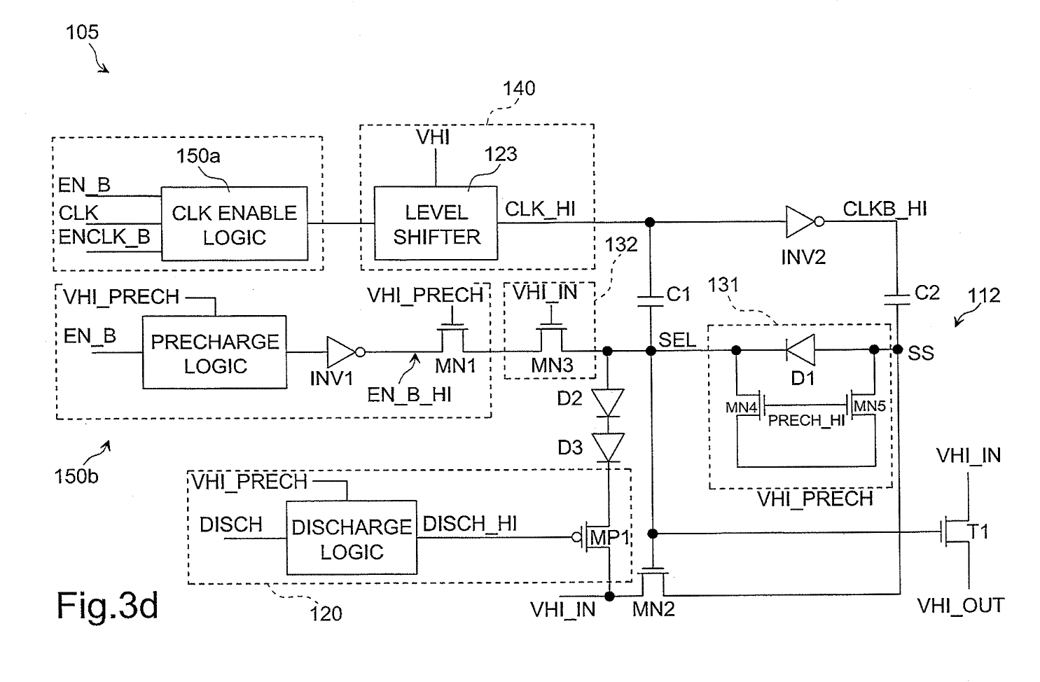

FIG. 3a discloses a first embodiment of the present invention. It is provided a high voltage switch circuit 100. Differently from the circuit shown in FIG. 1, discharge logic circuit 120 and protection circuits 131, 132 are provided in FIG. 3a.

The high voltage switch circuit 100 is provided to generate a control voltage Vg of a high voltage switch T1 at a control node SEL. The high voltage switch T1 has an input terminal IN and an output terminal and is configured to transfer a first high voltage VHI from the input terminal (VHI_IN) to the output terminal (VHI_OUT) appropriately biasing the control voltage Vg at the node SEL. Preferably the high voltage switch is a MOS transistor, particularly a NMOS transistor, the gate terminal of which is connected to the node SEL, the drain terminal is connected to the input terminal IN and the source terminal is connected to the output terminal OUT.

The high voltage switch circuit 100 includes a voltage-generating circuit that includes an input circuit 111 and a positive feed back loop circuit 112, and the voltage-generating circuit is configured to produce a voltage at a control gate of T1 in order to render T1 conductive or non-conductive.

The input circuit 111 is configured to transfer a predetermined pre-charge voltage VDD-VTHN to the control node SEL in response to a switch control signal EN_B, wherein VTHN is the threshold voltage of the transistors MN1. The input circuit 111 includes an inverter INV1 driven by the switch control signal EN_B and a MOS transistor MN1 having the gate terminal connected with the supply voltage VDD, a source or drain terminal supplied with the enable signal EN_B via the inverter INV1 and the drain or source terminal coupled with the node SEL via a MOS transistor MN3. At the ON state, the enable signal EN_B is at low logic level (i.e. at GND) and the node SEL is pre-charged at VDD-VTHN through the transistor MN1 and the PMOS transistor of the inverter INV1.

The high voltage switch circuit 100 includes a positive feedback loop 112 configured to transfer the high voltage VHI_IN to the control node SEL in response to the control voltage signal Vg. The positive feedback loop 112 includes a MOS transistor MN2 having the gate terminal connected with the node SEL, a source or drain terminal coupled with a node SS and the drain or source terminal supplied with the input voltage VHI_IN and a diode D1 connected between the nodes SS and SEL. The positive feedback loop 112 includes even two diodes D2 and D3 connected between the node SEL and the source or drain terminal of the transistor MN2 via a MOS transistor MP1.

The high voltage switch circuit 100 includes first C1 and second C2 capacitors for boosting the voltage Vg of the control node SEL and the voltage of the node SS of the positive feedback loop, respectively.

Preferably the high voltage switch circuit 100 receives a clock signal CLK applied to the capacitor C1 and coupled with the capacitor C2 by means of an inverter INV2.

The HVS circuit 100 has two stable states, the ON state and the OFF state.

The OFF state is obtained by keeping the enable signal EN_B at high logic level, for example the supply voltage VDD. The node SEL is kept at the low level, for example GND, through the transistor MN1 being in on state because its gate terminal receives the supply voltage VDD and the NMOS transistor of the inverter INV1 is in on state. With the node SEL at GND the NMOS transistor T1 is kept off, so that the node VHI_IN is not connected to the node VHI_OUT. Furthermore, no boosts occur on the nodes SEL and SS through the capacitors C1 and C2 because a logic cuts off the clock signal CLK when the HVS circuit is off.

The ON state is obtained by keeping the enable signal EN_B at low logic level (i.e. at GND); the node SEL is pre-charged at VDD-VTHN (wherein VTHN is the threshold voltage of the transistors MN1 and MN2) through the transistor MN1 and the PMOS transistor of the inverter INV1 and the node SS is pre-charged at the minimum voltage between VDD-2VTHN or VHI_IN through transistor MN2.

At the first falling edge of the signal CLK the node SEL is boosted down by −VDD towards the voltage −VTHN (neglecting the parasitic capacitance at the node SEL with respect to C1) through the capacitor C1. At the same time, the node SS, by means of the inverter INV2, is boosted up to 2VDD-2VTHN (neglecting the parasitic capacitance at the node SS with respect to C2) through the capacitor C2; in this way a voltage difference of 2VDD-VTHN is settled over the diode D1. If the inequality 2VDD-VTHN>VTHD (wherein VTHD is the threshold voltage of the diode D1) is kept, the diode D1 is on and the node SEL raises up to 2VDD-VTHN-VTHD (neglecting the charge sharing phenomenon between capacitances at the nodes SS and SEL).

At the following rising edge of the signal CLK, the node SEL is boosted up to 3VDD-VTHN-VTHD and, at the same time, the node SS is boosted down to VDD-2VTHN. In such a way the voltage difference of −2VDD-VTHN+VTHD is settled over the diode D1, which is turned off.

Successively, after the turning on of the transistor MN2, the node SS is charged up to 3VDD-2VTHN-VTHD.

At the following falling edge of the signal CLK, the node SEL is boosted down to 2VDD-VTHN-VTHD and, at the same time, the node SS is boosted up to 4VDD-2VTHN-VTHD. In such a way the voltage difference of 2VDD-VTHN is settled over the diode D1, which is turned on.

Successively, after the turning on of the diode D1, the node SEL is charged up to 4VDD-2VTHN-2VTHD.

At the following rising edge of the signal CLK, the node SEL is boosted up to 5VDD-2VTHN-2VTHD and, at the same time, the node SS is boosted down to 3VDD-2VTHN-VTHD. In such a way a voltage difference of 2VDD+VTHD is settled over the diode D1, which is turned off and so on.

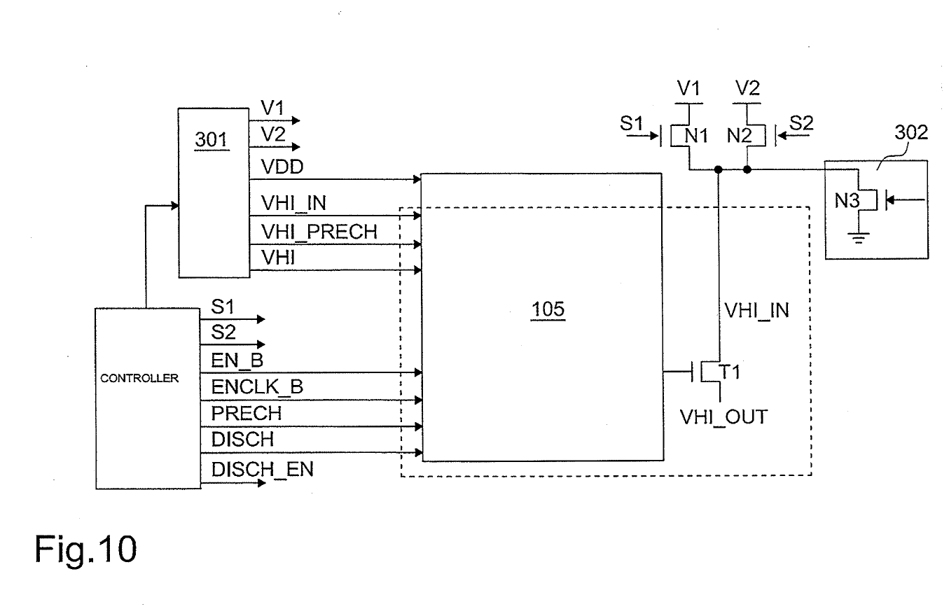

The high voltage switch circuit 100 includes a discharge circuit 120 configured to discharge the control node SEL during a beginning time period (while MP1 is conductive) of the discharge state and discharge the output terminal OUT during the discharge state, that is in absence of the high voltage VHI. Since the discharge state starts setting node VHI_IN at GND potential (i.e. since a discharger (shown in FIG. 10) coupled to the node VHI_IN starts discharging the node VHI_IN), the discharge circuit 120 performs an electric path to ground from the control node SEL and simultaneously maintains in on state the high voltage switch T1.

Preferably the discharge circuit 120 includes a DISCHARGE LOGIC block and the PMOS transistor MP1. The transistor MP1 is serially inserted in the positive feedback loop 112 and is coupled between the diode D3 and the source or drain terminal of the transistor MN2. The gate terminal of the transistor MP1 is controlled by the control signal DISCH_HI deriving from the logic block DISCHARGE LOGIC. The logic block DISCHARGE LOGIC is controlled from a logic signal DISCH and is supplied by a pre-charge voltage VHI_PRECH.

In the discharge state, the discharger as explained above is activated to discharge VHI_IN, and an electrical charge is discharged from VHI_OUT via on-state T1 transistor to VHI_IN (to the discharger which is at ground potential). In this state, the HVS circuit 100 manages to keep T1 transistor on-state.

More specifically, in the discharge state, the signal DISCH_HI is set to be the voltage VHI_PRECH. Since the voltage VHI_PRECH is significantly lower than the voltage at the node SEL that have been changed by the boosting capacitors, it happens that, at the beginning of the discharge of the node SEL, the transistor MP1 is still on: in this phase the node SEL will be partially discharged. In fact, when the input terminal IN of the transistor T1 starts discharging, the node SEL will follow it; the node SEL is at a voltage VHI_IN+2VTHD.

The transistor MP1 will switch off when the voltage difference between its source and gate becomes lower than its voltage threshold. After that, in the remaining part of the discharge, at the node SEL will be a pulse (due to the boost action) with a constant average. Particularly the node SEL discharges until the source terminal of the transistor MP1 has a voltage VHI_PRECH+VTHP wherein the voltage VTHP is the threshold voltage of the transistor MP1; when the voltage at the source terminal of the transistor MP1 is lower than VHI_PRECH+VTHP, the transistor MP1 turns off and the node SEL will stop discharging maintaining a voltage VHI_IN+2VTHD+VTHP. In this condition, the NMOS transistor T1 is always in on state and the discharge of the output terminal OUT occurs discharging the input terminal IN. After the discharging phase ends, the signal DISCH_HI is set at logic level 0 and the transistor T1 can be turned off by setting the signal EN_B at the logic level 1.

The transistor MP1 other than ensuring the node SEL to be high enough to assure the on state of the transistor T1 in the discharge phase, avoids a path between the voltages VHI_IN and VHI_PRECH through the transistors MN1, MP1, the diodes D2 and D3 and the block PRECHARGE LOGIC.

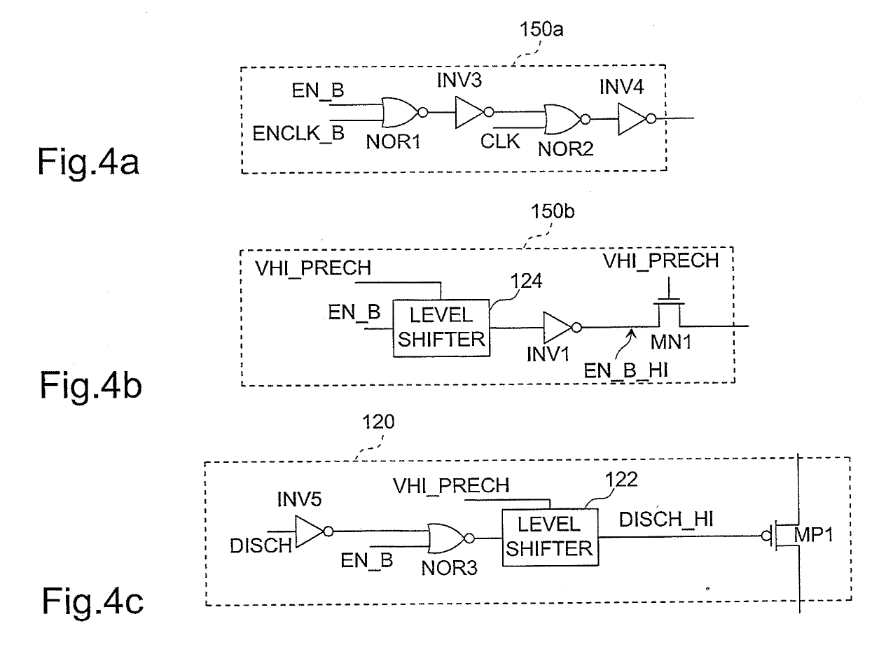

The block DISCHARGE LOGIC may be implemented, as shown in FIG. 4c, by a level shifter 122 having the voltage VHI_PRECH as supply voltage and controlled by the output signal from a NOR gate NOR3 having at the inputs the signal EN_B and the output signal of an inverter INV5 having at the input the logic signal DISCH.

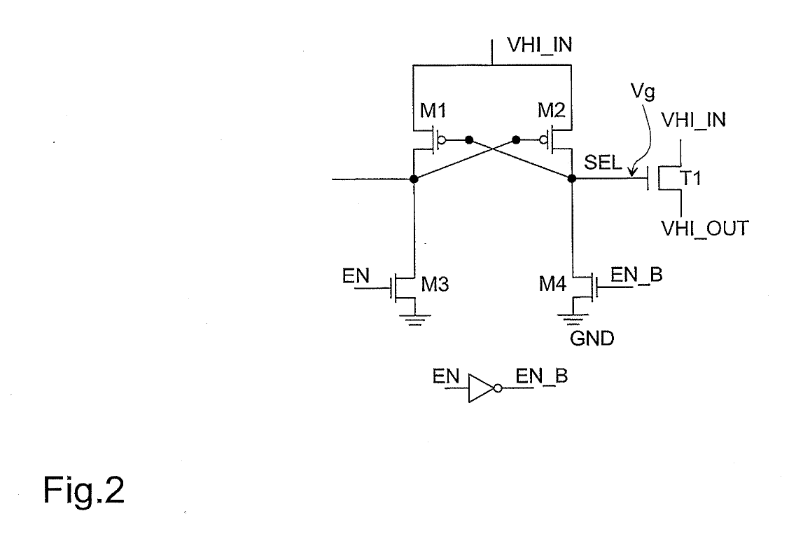

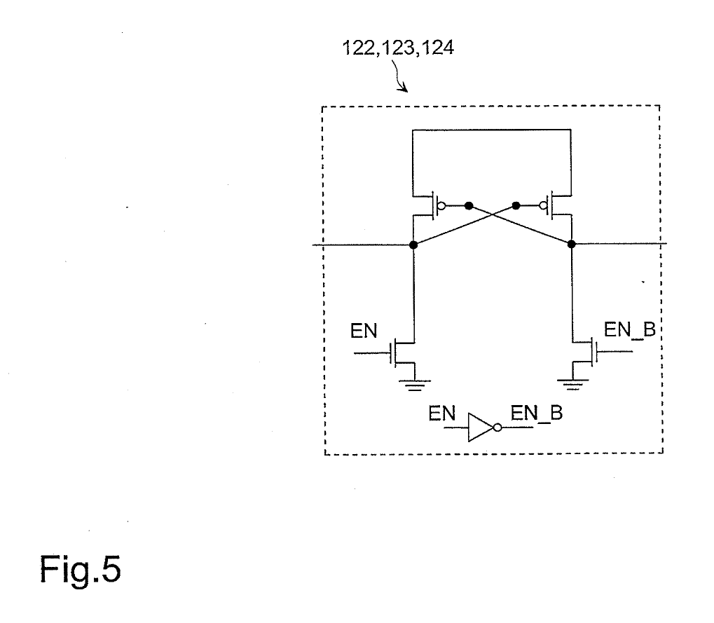

The level shifter 122 is shown in FIG. 5; the circuital configuration of the level shifter 122 is similar to the circuital configuration of the level shifter in FIG. 2 wherein the voltage VHI_PRECH is set in the place of the voltage VHI_IN and wherein the output signal is the control signal DISCH_HI in the place of the signal Vg.

Preferably the high voltage switch circuit 100 includes a protection circuit 131 for the MOS transistor MN2; the protection circuit 131 is configured to prevent hot switching of the transistor MN2. The hot switching phenomenon occurs, in the case that a great amount of current flows through a MOS transistor when the transistor is turned on, which drain-source voltage is higher than a prefixed threshold; this phenomenon once it starts is self-sustained. The protection circuit 131 is configured to limit the drain-source voltage of the transistor MN2 according to the SOA of said MOS transistor.

Preferably the protection circuit 131 is configured to maintain the voltage difference between the gate terminal SEL and the source terminal SS at the same voltage during the pre-charge phase; in this way the switching on of the transistor MN2 at high drain-source voltage is avoided. The protection circuit 131 is configured to pre-charge the node SS at the same voltage value of the node SEL when the same node SEL is precharged at a given value so as to turn off the transistor MN2. Only when the voltage at the node SEL is boosted by means of the capacitor C1 and the voltage at the node SEL becomes higher than the voltage at the node SS, the transistor MN2 turns on but the drain-source voltage is VHI_IN-VHI_PRECH+VTHN. The drain-source voltage is safe if the voltage VHI_PRECH is chosen appropriately.

The protection circuit 131 includes transistors MN4 and MN5 having the gate and drain terminals in common respectively and the source terminals connected across the diode D1; the drain terminals are connected to the voltage VHI_PRECH while the gate terminals are connected to a signal PRECH_HI.

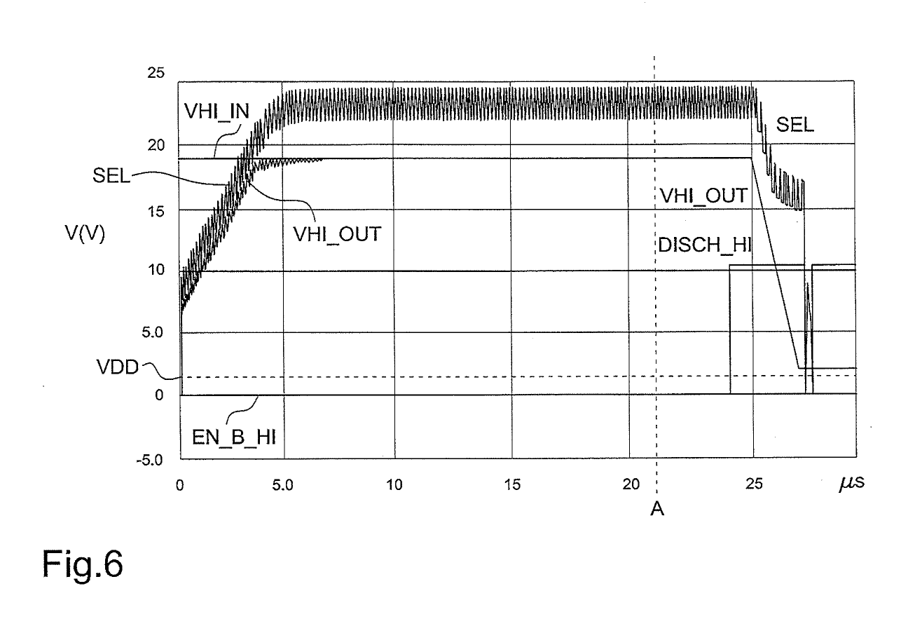

In such case that high voltage, for example 19 volt such as shown in FIG. 6, is applied to the node VHI_IN during the boosting state including the pre-charge state (the pre-charge state is a state that precedes the boosting state provided by the capacitors), the drain-source voltage of MN2 is suppressed low enough by choosing appropriate VHI_PRECH, and the hot switching phenomenon of MN2 is prevented. More specifically, when the HVS circuit 100 has to be switched on and the signal VHI_IN is too high with respect to hot switching issues, the signal PRECH_HI is put high in order to bring the nodes SEL and SS up to VHI_PRECH-VTHN but keeping SEL and SS at the same voltage so that MN2 is kept off. When the boosting start (by CLK_HI switching), the voltage Vg at the node SEL becomes higher than the voltage at the node SS and the transistor MN2 is switched on with VD=VHI_IN and VS=PRECH_HI-VTN: so, these voltages have to be chosen in order to have VDS low enough to avoid hot switching.

Preferably the high voltage switch circuit 100 includes another protection circuit 132, gated by VHI_PRECH, for the MOS transistor MN1. The protection circuit 132 is configured to prevent hot switching of the transistor MN1. The protection circuit 132 is configured to limit the drain-source voltage of the transistor MN1 according to the SOA of said MOS transistor.

Preferably the protection circuit 132 includes the transistor MOS MN3 used in a cascode configuration with the transistor MN1. In the case that the transistor MN1 is exposed to hot switching risk when the high voltage switch circuit is turned off, the transistor MN3 ensures that the drain-source voltage of MN 1 is low enough to guarantee the absence of hot switching phenomenon of the transistor MN1. When the switch is turned off (after boosting state), the transistor MN3 has drain-source voltage such as boosted high voltage−(VDD-VTHN), and the transistor MN1 has drain-source voltage such as (VDD-VTHN)−ground voltage. Those drain-source voltages are within SOA. In another case that, as explained below in FIG. 3d, the transistor MN3 having the gate supplied with VHI_IN and the transistor MN 1 having the gate supplied with VHI_PRECH are constituted, the transistor MN3 has drain-source voltage such as boosted high voltage−(VHI_PRECH_VTHN), and the transistor MN1 has drain-source voltage such as (VHI_PRECH_VTHN)−ground voltage. Those drain-source voltages are within SOA, and especially this can be obtained by choosing appropriate voltage value of VHI_PRECH. Therefore, hot switching can be avoided.

FIG. 3b shows a second embodiment of the present invention. Differently from the circuit shown in FIG. 1, a circuit 140 and protection circuits 131, 132 are provided in FIG. 3b.

It is provided a high voltage switch circuit 101 adapted to generate a control voltage Vg of a high voltage switch T1 at a control node SEL; the high voltage switch circuit 101 includes all the elements of the high voltage switch circuit 100 in FIG. 3a without the discharging circuit 120. The high voltage switch circuit 101 includes, in the place of the signal CLK of the high voltage switch circuit 100 in FIG. 3a, a circuit 140.

The circuit 140 is configured to provide a boosting clock supplied with a voltage VHI that is higher than the supply voltage VDD. The supply voltage VDD is supplied to and used in the device, such as an internal circuit of the device. In FIG. 3b, the supply voltage VDD is supplied to the gate of the transistor MN1. The CLK ENABLE LOGIC circuit, as will be explained below in FIG. 3d, may be supplied with the supply voltage VDD.

The circuit 140 may be implemented by a level shifter 123 (shown in FIG. 5) configured to increase the boosting voltage from VDD of prior art to VIII. The voltage VHI is provided by a regulator and it is independent from the supply voltage variations, i.e. it is not affected by VDD drops. The device 140 has at the input the signal CLK and outputs the signal CLK_HI at one terminal of the capacitor C1 and the inverted signal CLKB_HI (by means of the inverter INV2) at one terminal of the capacitor C2.

The level shifter 123 is shown in FIG. 5; the circuital configuration of the level shifter 123 is wherein the voltage VHI is set in the place of the voltage and wherein the output signal is the control signal CLK_HI in the place of the signal Vg.

As described above, the inequality 2VDD-VTHN>VTHD is required for correct work of the switch circuit 101 in the boosting state. Voltage difference between input and output nodes of the diode D1 is indicated by 2VDD-VTHN-VTHD. In FIG. 3b, instead of VDD, the level shifter 123 is supplied with the voltage VHI higher than VDD. Therefore, the inequality is satisfied in the boosting state, even if the body effect occurs and the threshold voltage VTHN of the NMOS transistor included in the switch circuit 101 increases. Thus, the switch circuit 101 works correctly without any problems in the boosting state.

FIG. 3c shows a third embodiment of the present invention. Differently from the circuit shown in FIG. 1, a circuit 150 including 150a and 150b, and protection circuits 131, 132 are provided in FIG. 3c.

It is provided a high voltage switch circuit 102 adapted to generate a control voltage Vg of a high voltage switch T1 at a control node SEL; the high voltage switch circuit 102 includes all the elements of the high voltage switch circuit 100 in FIG. 3a without the discharging device 120. The high voltage switch circuit 102 includes, in the place of the input circuit 111 of the high voltage switch circuit 100 in FIG. 3a, an input circuit 150.

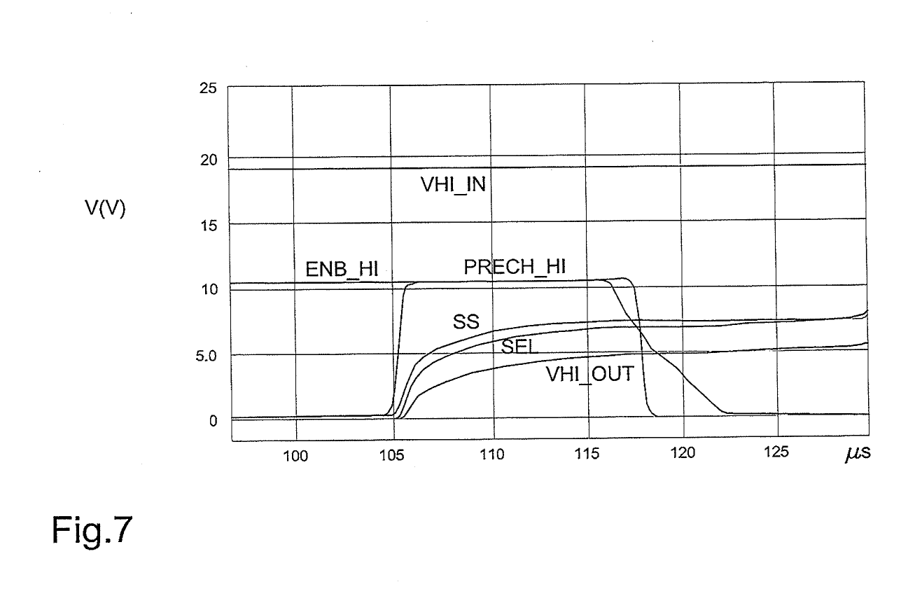

The input circuit 150 includes the circuits 150a and 150b. The input circuit 150a and the capacitors C1, C2 are configured to charge the node SEL at a boosted voltage which is high voltage about 23 volt as shown below in FIG. 6. The circuit 150b is configured to charge the node SEL at a voltage VHI_PRECH-VHTN which is a medium voltage about 7 volt as shown below in FIG. 7, particularly a voltage has a range between VHI and VDD. The voltage VHI_PRECH-VHTN may also be a low voltage, particularly a voltage lower than VDD. In those ways, the high voltage switch may be used not only to deliver high voltage but even to deliver medium or low voltage. The high voltage is produced at the SEL node due to the precharge of the circuit 150b and the boosting of the circuit including the capacitors. The medium voltage is produced at the SEL node due to the precharge of the circuit 150b, and in this case, the boosting is refrained.

The circuit 150b is configured to produces a pre-charge voltage VHI_PRECH-VHTN in response to a switch control signal EN_B.

The circuit 150b includes a PRECHARGE LOGIC block driven by the switch control signal EN_B, an inverter INV1, and a MOS transistor MN1 having the gate terminal connected with the pre-charge voltage VHI_PRECH, a source or drain terminal supplied with the enable signal EN_B_HI and the drain or source terminal coupled with the node SEL. At the ON state, the enable signal EN_B is at high logic level (i.e. the signal EN_B_HI is at VHI_PRECH), and the node SEL is pre-charged at VHI_PRECH-VHTN (wherein VTHN is the threshold voltage of the transistors MN1) through the transistor MN1 and the PMOS transistor of the inverter INV1.

Preferably, as shown in FIG. 4b, the circuit 150b includes a level shifter 124 that is substantially the same as the PRECHARGE LOGIC block shown in FIG. 3c. The PRECHARGE LOGIC block may also be constituted so as to include the level shifter 124. The inverter INV1 includes an input node coupled to the level shifter 124 and an output node coupled to MN1.

The lever shifter 124 is described in more detail in FIG. 5. The circuital configuration of the level shifter 124 is similar to the circuital configuration of the level shifter in FIG. 2 wherein the voltage VHI_PRECH is set in the place of the voltage VHI_IN. In FIG. 5, input node (left side node) of the level shifter 124 is supplied with the signal EN_B and the output node (right side node) thereof is coupled to input node of the INV1. The enable signal EN_B controls the level shifter 124.

Also, choosing appropriately the voltage VHI_PRECH, no boosting is needed to deliver a medium or a low voltage, hence limiting power consumption.

The circuit 150a includes a logic block CLK_ENABLE_LOGIC that receives the signals EN_B, ENCLK_B, and clock pulses CLK. For example, the signal EN_B is known as an enable switch signal or a switch control signal that enable to render the high voltage switch circuit active. The signal EN CLOCK is known as an enable clock signal that enable to render a circuit that provide clock pulses.

The circuit 150a is configured to produce a plurality of clock signals at CLK1 node. The CLK1 node is coupled to C1 and input node of INV2. The output node of INV2 is coupled to C2. When boosting by capacitors C1 and C2 is required, the circuit 150a provides the clock signals and inverted ones thereof respectively to capacitor C 1 and C2 in order to boost the SEL node. On the other hand, when boosting by capacitors C 1 and C2 is not required, the circuit 150a does not provide the signal to stop the boosting of the capacitors C1 and C2.

Preferably, as shown in FIG. 4a, the logic block CLK_ENABLE_LOGIC includes a NOR gate NOR1 having at the input the logic signals EN_B and ENCLK_B and the output signal of which controls an inverter INV3. The output signal of the inverter INV3 is at the input of a NOR gate NOR2 with the signal CLK. The output signal of the NOR gate NOR2 controls the inverter INV4 the output signal of which is the signal CLK1 at one terminal of the capacitor C1 having the other terminal connected with the node SEL.

FIG. 3d shows a fourth embodiment of the present invention. Differently from the circuit shown in FIG. 1, discharge circuit 120, protection circuits 131, 132, circuit 140, and circuit 150 (including 150a and 150b) are provided in FIG. 3d.

It is provided a high voltage switch circuit 105 adapted to generate a control voltage Vg of a high voltage switch T1 at a control node SEL; the high voltage switch circuit 105 includes all the elements of the high voltage switch circuit 100 in FIG. 3a with the circuits 140 and 150 in FIGS. 3b and 3c in the place of the signal CLK and the input device 111.

The working phases of the high voltage switch circuit 105 are shown in time diagrams of FIGS. 6-8 considering a supply voltage VDD=1.5 Volt that is shown as dot line in FIG. 6. The supply voltage VDD is a voltage that is supplied from external to the device.

FIG. 6 shows a waveform representing a high voltage switching operation of the high voltage switch circuit as shown in FIG. 3d.

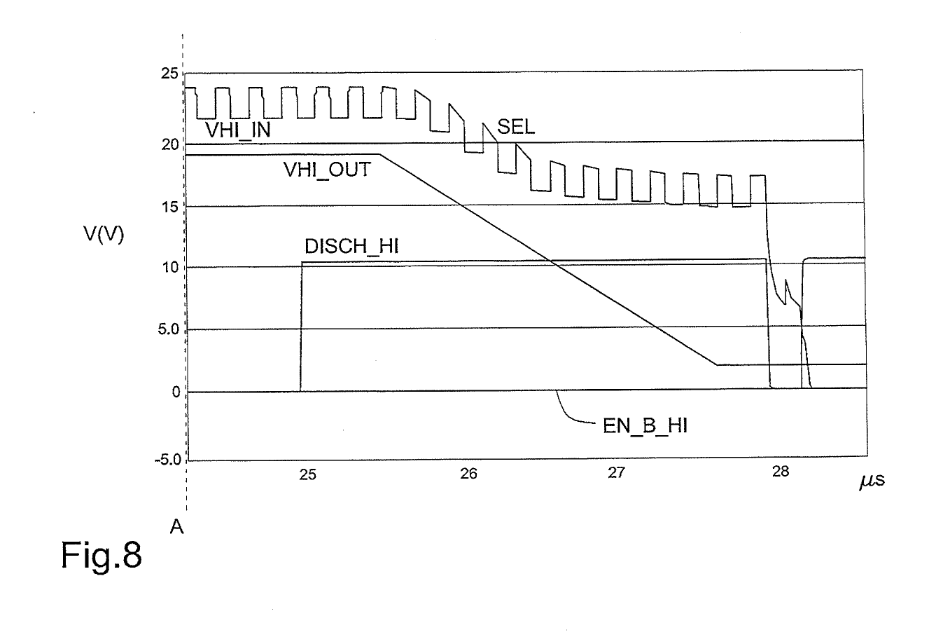

Time period from 0 to time 21.5 μs indicated by dot line A corresponds to the charge state. The signal EN_B_HI is high at very beginning of the period, and then it turns low. Capacitors work to boost a voltage at SEL node in response to the clock pulses of the signal CLK supplied thereto. The SEL node is charged from about 10 volt to about 23 volt. Voltage supplied with VHI_IN is about 19v. As following the charging of SEL, voltage at VHI_OUT increases and reaches about 19 volt that is the same or substantially same as the voltage at VHI_IN. The input high voltage is delivered to the output at VHI_OUT node, by keeping the transistor T1 in on state. Next, time period after 21.5 μs indicated by dot line A correspond to the discharge state. This time period is shown more detail in FIG. 8. As explained above, T1 is kept to be rendered conductive in the discharge state as well.

FIG. 7 shows a waveform representing an intermediate voltage switching operation of the high voltage switch circuit such as shown in FIG. 3d.

At the beginning, the ENB_HI is high. The signal PRECH_HI is low. Next, the signal PRECH_HI turns high and then after short time period turns low, which is an impulse signal; during the pulse of said signal the nodes SEL and SS are charged up to VHI_PRECH-VTHN (about 7 volt in this particular case) and the voltage at the terminal OUT goes up to VHI_PRECH-2VTHN (about 5 volt in this particular case). In these conditions, also without boosting, the HVS circuit is able to deliver voltages up to about 5 volt; changing the value of the voltage VHI_PRECH, higher voltages within the SOA limits of the whole circuit (e.g. up to about 12 Volt in some technologies) may be managed without boosting, saving power consumption. Furthermore, since the nodes SEL and SS are at the same voltage value, the transistor MN2 has not switching risks.

FIG. 8 shows a waveform representing a discharge switching operation of the high voltage switch circuit such as shown in FIG. 3d. The figure corresponds to a portion of FIG. 6 that is after 21.5 μs indicated by dot line A. At the time A, the signal EN_B_HI is low, and DISCH_HI is low. SEL is high voltage such as about 23 volt due to the boosting. Since the transistor T1 is on, VHI_IN and VHI_OUT is the same in voltage level as each other. After the time A, when the signal DISCH_HI is set to high, discharge of VHI_IN node starts. In the figure, the rectangular pulse signal DISCH_HI identifies the discharge state. In this state, VHI_IN is being discharged by the discharger coupled to VHI_IN node. According to this discharge, the voltage VHI_OUT closely follows the voltage VHI_IN through conductive T1 transistor. The node SEL in this state begins discharging, as keeping a voltage higher enough than VHI_IN (VHI_IN+VTHP+2VTHD) to ensure the transistor T1 is kept on. The node SEL stops discharging when it gets the voltage VHI_PRECH+VTHP+2VTHD because the transistor MP1 switches off. The discharge operation ends, when or after the signal DISCH_HI goes low. The node SEL goes down to the voltage VTHP+2VTHD. When the switch T1 is turned off (by setting the signal EN_B to 1) the node SEL is grounded.

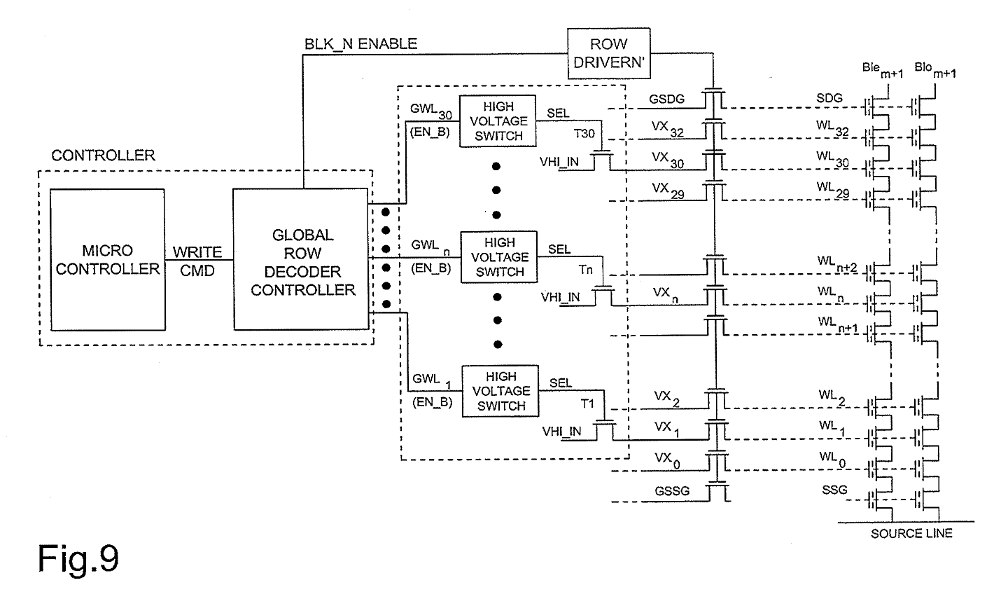

FIG. 9 shows a NAND device having the high voltage switch circuit shown in one of FIGS. 3a to 3d. FIG. 9 refers to one flash memory block of a 32 word line WL₀ . . . WLₙ . . . WL₃₁ and multiple bit lines BL₀ . . . Bl_{K}. The NAND device includes MOS transistor T0, T1 . . . Tn T30, T31 the gate terminal SEL of which is controlled by respective high voltage switch circuits 100. The enable signals EN_B of said high voltage switch circuits 100 are represented by the signals GWL₀, GWL₁ . . . GWLₙ . . . GWL₃₀, GWL₃₁ at the output from a GLOBAL ROW DECODER CONTROLLER; the last receives a write command WRITE CMD from the MICROCONTROLLER. A CONTROLLER may include the GLOBAL ROW DECODER CONTROLLER and MICROCONTROLLER.

When one of the switches T0, T1 . . . Tn T30, T31 is enabled, the high voltage VHI_IN is passed to a selected word line. When a word line WLₙ is selected for a program operation, the related HVS circuit 100 is enabled so that the high voltage pass through the transistor Tn to VXₙ; another switch driven by the block ROW DRIVER_N and controlled by the block GLOBAL ROW DECODER CONTROLLER by means of the signal BLK_N ENABLE allows the passage of the voltage VHI_IN to the selected word line WLₙ.

A plurality of dischargers may be designed in FIG. 9, each discharger being coupled respectively to associated one of VHI_IN nodes shown in FIG. 9 in order to discharge VHI_IN nodes. Preferably, instead of the plural dischargers, one discharger is coupled in common to the VHI_IN nodes, and thus reduction of design layout area can be obtained. To design such one discharger is accomplished without any discharging problems due to the high voltage switch circuit such as explained above in FIGS. 3a and 3d.

A more detailed part of the NAND memory device in FIG. 9 is shown in FIG. 10. The block CONTROLLER provides the control signals PRECH, DISCH, EN_B, ENCLK_B, DISCH_EN to the high voltage switch 105 to control the transistor T1. The high voltage switch 105 may include a plurality of high voltage switches as shown in FIG. 9. The block CONTROLLER controls a voltage generator 301 adapted to provide the voltage VHI, VHI_PRECH, VHI_IN, and VDD (a power supply voltage of NAND device) to the high voltage switch 105 and adapted to provide an high voltage V1 (about 20 volt) and the voltage V2 (about 5 Volt) that are different from each other. For example V1=20v is applied as a selected voltage to a selected word line coupled to selected cell under program operation of NAND flash memory, and V2=5 Volt) is applied as an unselected voltage to a unselected word line coupled to unselected cells under the program operation. Also block CONTROLLER is configured to control by means of write commands S1 and S2 the transistors N1 and N2 to allow the passage of the voltages V1 or V2 to the terminal IN of the transistor T1 in a write operation of the NAND device. A discharger 302 is shown in FIG. 10. The discharger is configured to discharge, when activated, the node, and it includes a transistor N3 coupled between the VHI_IN node and a ground potential. The transistor N3 includes a control gate supplied with a control signal, for example a discharge enable signal DISCH_EN supplied from the controller. In the charging state, the discharger can be deactivated or off so as not to produce an electrical path between the VHI_IN node and the ground potential. On the other hand, when or after the discharge state starts, the discharger can be activated or on so as to produce the electrical path between the VHI_IN node and the ground potential, and at this time, the transistor N3 changes from non-conductive to conductive in response to the control signal supplied at the control gate thereof.

Although the present invention and its advantages have been described in detail, it should be understood that various changes, substitutions and alterations can be made herein without departing from the spirit and the scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, composition of matter, means, methods, or steps.

What is claimed is:

1. A device comprising:
a first transistor coupled between an input terminal and an output terminal and including a control gate;
a voltage-generating circuit configured to produce a voltage to be supplied to the control gate of the first transistor, and
a discharge circuit coupled between the input terminal of the first transistor and the control gate of the first transistor, the discharge circuit responding to a discharge signal to perform a discharge operation such that an electrical charge is discharged from the output terminal to the input terminal of the first transistor.

2. The device according to claim 1, wherein the discharge circuit includes:
a MOS transistor having a first terminal coupled to the control gate of the first transistor and a second terminal coupled to the input terminal of the first transistor, and including a control gate supplied with the discharge signal.

3. The device according to claim 2, wherein the discharge circuit further includes:
a discharge logic circuit configured to provide the control gate of the MOS transistor with the discharge signal taking one of a first level and a second level, the first and second levels being different from each other.

4. The device according to claim 1, wherein the discharge operation starts when the discharge signal changes from a second level to a first level, and the discharge operation ends, when or after the discharge signal changes from the first level to the second level, the first and second level being different from each other,
and wherein the discharge circuit is configured to render the first transistor conductive while the discharge level takes the first level.

5. The device according to claim 1, wherein the voltage-generating circuit includes:
a first diode circuit including an input node and an output node coupled to the control gate of the first transistor;
a first capacitor including one end coupled to the control gate of the first transistor and the other end supplied with a clock signal;
a second capacitor including one end coupled to the input node of the first diode circuit and the other end supplied with an inverted one of the clock signal;
a second transistor coupled between the input node of the first diode circuit and the input terminal of the first transistor, and including a control gate coupled both to the control gate of the first transistor and to the output node of the first diode circuit; and
a second diode circuit inserted between the control gate of the first transistor and the discharge circuit.

6. The device according to claim 5, further comprising:
a clock-generating circuit configured to supply the clock signal and the inverted one of the clock signal respectively to the first and second capacitors, the clock-generating circuit being supplied with a voltage higher than a supply voltage of the device.

7. The device according to claim 5, further comprising:
a precharge circuit configured to charge, when activated in response to a switch control signal, the control gate of the first transistor;
a clock-generating circuit configured to supply, when activated, the clock signal and the inverted one of the clock signal respectively to the first and second capacitors, the clock-generating circuit being activated in response to the switch control signal and an clock enable signal different from the switch control signal.

8. The device according to claim 7, wherein the precharge circuit establishes a voltage higher than a supply voltage of the device at the control gate of the first transistor to charge the control gate of the first transistor.

9. The device according to claim 7, further comprising:
a first protection transistor inserted between the precharge circuit and the control gate of the first transistor, and including a control gate supplied with a voltage higher than a supply voltage of the device.

10. The device according to claim 5, further comprising:
a first protection transistor coupled between the output node of the first diode circuit and a precharge node, and including a control gate; and
a second protection transistor coupled between the input node of the first diode circuit and the precharge node, and including a control gate coupled to the gate of the first protection transistor.

11. The device according to claim 1, further comprising:
a protection circuit configured to protect a second transistor included in the voltage-generating circuit from a hot switching phenomenon.

12. The device according to claim 1, further comprising a non-volatile memory including a cell and a word line associated with the cell, the word line being coupled to the output terminal of the first transistor.

13. The device according to claim 1, wherein the discharge circuit stops, after producing an electrical path from the control gate of the first transistor to the input terminal of the first transistor, producing the electrical path, to render the first transistor conductive in the discharge operation.

14. A device comprising:
an internal circuit operating on a first voltage;
a first transistor including a control gate;
a clock-generating circuit configured to provide a boosting clock signal; and
a boost circuit configured to produce a voltage to be supplied to the control gate of the first transistor in response to the boosting clock signal provided by the clock-generating circuit,
the clock-generating circuit operating on a second voltage that is higher than the first voltage.

15. The device according to claim 14, wherein the clock-generating circuit comprises a level shifter supplied with the second voltage, and wherein the second voltage is a supply voltage that is supplied to the device.

16. A device comprising:
a first transistor coupled between an input terminal and an output terminal and including a control gate;
a first input circuit configured to produce a first pre-charge voltage at the control gate of the first transistor,
a first boost circuit configured to, when activated, boost the first pre-charge voltage to produce a first boost voltage at the control gate of the first transistor, the first boosting circuit being configured to, when deactivated, refrain from boosting the first pre-charge voltage, so that the control gate of the first transistor receives the first pre-charge voltage produced by the first input circuit, the first pre-charge voltage and the first boost voltage being different from each other.

17. The device according to claim 16, wherein the first boost circuit includes:
a capacitor circuit that boosts the first pre-charge voltage in response to a plurality of clock pulses; and
a clock enable logic circuit that outputs the clock pulses in response to a clock signal, a switch control signal and an clock enable signal that are different from one another.

18. The device according to claim 16,
a second transistor coupled between an input terminal and an output terminal and including a control gate;
a second input circuit configured to produce a second pre-charge voltage at the control gate of the second transistor,
a second boost circuit configured to, when activated, boost the second pre-charge voltage to produce a second boost voltage at the control gate of the first transistor, the second boosting circuit being configured to, when deactivated, refrain from boosting the second pre-charge voltage, so that the control gate of the second transistor receives the second pre-charge voltage produced by the second input circuit, the second pre-charge voltage and the second boost voltage being different from each other.

19. The device according to claim 18, further comprising:
a non-volatile memory array includes a plurality of cells, first and second ones of the cells being associated respectively with the first and second transistors, the first cell receiving the first pre-charge voltage as an unselected voltage in a write operation of the non-volatile memory array, and the second cell receiving the second boost voltage as a selected voltage in the write operation of the non-volatile memory array.

20. The device according to claim 18, further comprising:
a control circuit configured to provide the first input circuit and the first boost circuit with first control signals to select one of the first pre-charge voltage and the first boost voltage, and the control circuit being configured to provide the second input circuit and the second boost circuit with second control signals to select one of the second pre-charge voltage and the second boost voltage.
